(19) United States
(12) Patent Application Publication
(10) Pub. No.: US 2011/0292737 A1
(43) Pub. Date: Dec. 1, 2011

(54) NONVOLATILE MEMORY APPARATUS

(75) Inventor: Won Beom CHOI, Icheon-si Gyeonggi-do (KR)

(73) Assignee: HYNIX SEMICONDUCTOR INC., Icheon-si (KR)

(21) Appl. No.: 12/983,068

(22) Filed: Dec. 31, 2010

(30) Foreign Application Priority Data
May 31, 2010 (KR) 10-2010-0051363

(51) Int. Cl. G11C 16/06

(52) U.S. Cl. 365/185.25

(57) ABSTRACT

A nonvolatile memory apparatus includes: a plurality of drain selection switches coupled to a plurality of memory cell strings, respectively; and a drain selection switch controller configured to selectively drive a drain selection switch coupled to an even bit line or a drain selection switch coupled to an odd bit line, in response to a page address and a global drain selection signal.

### CROSS-REFERENCES TO RELATED APPLICATION

The present application claims priority under 35 U.S.C. §119(a) to Korean application number 10-2010-0051363, filed on May 31, 2010, in the Korean Intellectual Property Office, which is incorporated herein by reference in its entirety.

### BACKGROUND

1. Technical Field

The present invention relates generally to a semiconductor integrated circuit, and more particularly to a nonvolatile memory apparatus.

2. Related Art

A flash memory apparatus is a type of nonvolatile memory apparatus which can electrically program and erase data without not requiring a refresh operation. In particular, a NAND flash memory apparatus has an advantage in that it can store a large volume of information due to a plurality of memory cells sharing a drain or source are coupled in series to form one cell string.

In general, when data is programmed into a flash memory apparatus, a verification process is also performed for verification of whether the desired data is accurately recorded or not. Such a verification process is performed in a similar manner to a read operation.

During a verification or read operation of the flash memory apparatus, a voltage-level-based sensing scheme may be used. In this case, a cell string coupled to an even bit line and a cell string coupled to an odd bit line are discriminated in performing a verification or read operation.

FIG. 1 is a diagram explaining a verification or read operation in a conventional flash memory apparatus.

Referring to FIG. 1, the conventional flash memory apparatus 10 includes a memory cell block 12, a bit line selector 14, icy and a page buffer 16.

The memory cell block 12 includes a plurality of drain selection switches driven by a drain selection signal DSL, a memory cell array 121, and a plurality of source selection switches driven by a source selection signal SSL.

One string cell is formed by a drain selection switch, n+1 memory cells coupled in series to the drain selection switch, and a source selection switch coupled to a source terminal of the last memory cell among the memory cells coupled in series, and one page is formed by a plurality of memory cells coupled to one word line WL.

Bit lines BLe and BLo are extended from drain terminals of the respective drain selection switches and coupled to the bit line selector 14.

The verification or read operation of the flash memory apparatus is performed for the respective memory cells coupled to the even bit line BLe and the odd bit line BLo.

For example, during a verification or read operation for a memory cell coupled to the even bit line BLe, a ground voltage VSS is applied to a verification voltage application terminal VIRPWR. While an even discharge signal DISCHE is disabled, an even bit line selection signal SELBLE, and a sensing control signal PBSENSE are enabled. Furthermore, while an odd discharge signal DIDCHO is enabled, an odd bit line selection signal SELBLO is disabled.

Similarly, during a verification or read operation for a memory cell coupled to the odd bit line BLo, the ground voltage VSS is applied to the verification voltage application terminal VIRPWR. While the odd discharge signal DISCHO is disabled, the odd bit line selection signal SELBLO and the sensing control signal PBSENSE are enabled. Furthermore, while the even discharge signal DISCHE is enabled, the even bit line selection signal SELBLE is disabled. Accordingly, the ground voltage VSS is applied to the even bit line BLe, and the odd bit line BLo is precharged with a predetermined potential.

During a verification or read operation for the even bit line BLe, the odd bit line BLo is coupled to a ground terminal, and a predetermined potential is applied to the even bit line BLe coupled to a memory cell which is to be verified or read by a precharge voltage of the page buffer 16. Then, data is stored in a latch of the page buffer 16.

That is, while the precharge voltage is applied to the even bit line BLe, the ground voltage is applied to the odd bit line BLo. Therefore, a parasitic capacitance corresponding to a capacitance owing due to the precharged bit line may occur. This will be described in detail with reference to FIG. 2.

FIG. 2 is a diagram explaining an influence of parasitic capacitance in the flash memory apparatus of FIG. 1.

FIG. 2 illustrates a parasitic capacitance caused when the even bit line BLe is selected to receive a precharge voltage and when the odd bit line BLo is not selected and receives a ground voltage VSS. Referring to FIG. 2, it can be seen that there exists a parasitic icy capacitance Cc occurring between the even bit line BLe and the adjacent odd bit line BLo as well as a parasitic capacitance Cg1 occurring between the even bit line BLe and the ground terminal VSS and a parasitic capacitance Cg2 occurring between the odd bit line BLo and the ground terminal VSS. In this state, the parasitic capacitance Cc between the even bit line BLe and the adjacent odd bit line BLo occupies 90% of the entire parasitic capacitance.

The parasitic capacitance may act as a factor which increases an operation current of the flash memory apparatus, thereby reducing operation efficiency of the flash memory apparatus.

With increased high integration of the flash memory apparatus, current consumption of one chip also increases gradually. In particular, the current consumption of a bit line approaches 50% of the current consumption of one chip. Therefore, the parasitic capacitance between a precharged bit line and a grounded bit line may act as a factor which determines the entire current consumption of the flash memory apparatus.

### SUMMARY

In one embodiment of the present invention, a nonvolatile memory apparatus includes: a plurality of drain selection switches respectively coupled to a plurality of memory cell strings, respectively; and a drain selection switch controller configured to selectively drive a drain selection switch coupled to an even bit line or a drain selection switch coupled to an odd bit line, in response to a page address and a global drain selection signal.

In another embodiment of the present invention, a nonvolatile memory apparatus includes: a plurality of drain selection switches respectively coupled between a cell string and bit lines, respectively, the cell string including a plurality of memory cells coupled in series; a page decoder configured to output a global even drain selection signal and a global odd drain selection signal in response to a verification or read command for the cell string; and a drain selection switch driving unit configured to select an even bit line or odd bit line in response to the global even drain selection signal and the global odd drain selection signal.

### BRIEF DESCRIPTION OF THE DRAWINGS

Features, aspects, and embodiments are described in conjunction with the attached drawings, in which:

FIG. 1 is a diagram explaining a verification or read operation in a conventional flash memory apparatus;

FIG. 2 is a diagram explaining an influence of parasitic capacitance in the flash memory apparatus of FIG. 1;

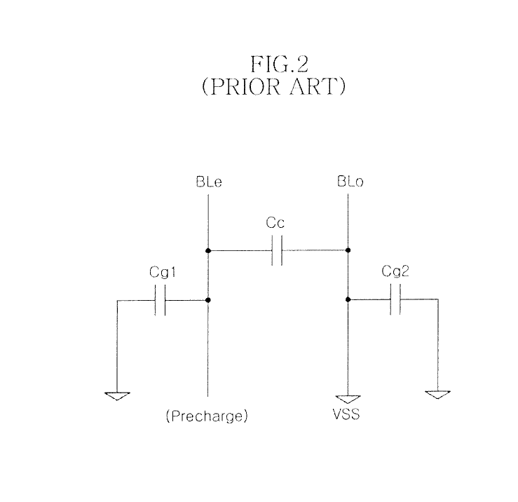

FIG. 3 is a configuration diagram of a nonvolatile memory apparatus according one embodiment;

FIG. 4 is a configuration diagram of a page decoder of FIG. 3;

FIG. 5 is a configuration diagram of a bit line selector of FIG. 3; and

FIG. 6 is a diagram explaining an influence of parasitic capacitance in the nonvolatile memory apparatus of FIG. 3.

### DETAILED DESCRIPTION

Hereinafter, a nonvolatile memory apparatus according to an embodiment of the present invention will be described below with reference to the accompanying drawings through exemplary embodiments.

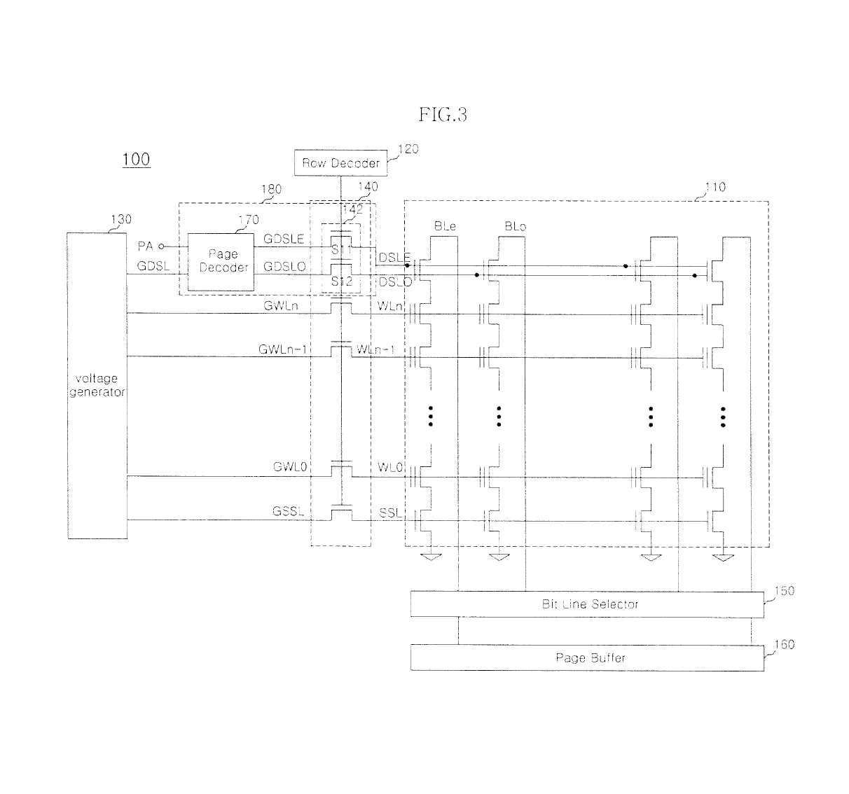

FIG. 3 is a configuration diagram of a nonvolatile memory apparatus according one embodiment.

Referring to FIG. 3, the nonvolatile memory apparatus 100 according to an embodiment includes a memory cell block 110, a row decoder 120, a voltage generator 130, a block selector 140, a bit line selector 150, a page buffer 160, and a page decoder 170. Examples of the nonvolatile memory apparatus 100 may include a flash memory apparatus.

The row decoder 120 is configured to generate a block selection signal. The block selector 140 is configured to apply a voltage generated by the voltage generator 130 to the memory cell block 110 according to the block selection signal generated from the row decoder 120.

The bit line selector 150 is configured to select a desired bit line during a program/verification/read operation, and the page buffer 160 is configured to transfer data to a memory cell or receive and store data stored in a selected memory cell through the bit line selected by the bit line selector 150.

The page decoder 170 is configured to output a global even drain selection signal GDSLE and a global odd drain selection signal GDSLO in response to a global selection signal GDSL generated by the voltage generator 130 and a page address PA.

The block selector 140 includes a drain selection switch driving unit 142 which includes a first switching element S11 and a second switching element S12. The first switching element S11 is configured to be driven according to the block selection signal outputted from the row decoder 120 and to receive the global even drain selection signal GDLSE to output an even drain selection signal DSLE. The second switching element S12 is configured to be driven according to the block selection signal outputted from the row decoder 120 and to receive the global odd drain selection signal GDSLO to output an odd drain selection signal DSLO.

The page decoder 170 and the drain selection switch driving unit 142 decide whether or not to drive a drain selection switch coupled to an even bit line or odd bit line. From this aspect, the page decoder 170 and the drain selection switch driving unit 142 together could be referred to as a drain selection switch controller 180.

Some flash memory apparatuses operate in such a way that all drain selection switches are turned on by one global drain selection signal GDSL during a verification or read operation and that the control for unselected bit lines is performed by the bit line selector such as 150 in FIG. 3.

In an embodiment of the present invention, however, the global even drain selection signal GDSLE and the global odd drain selection signal GDSLO are generated in response to the global drain selection signal GDSL and the page address PA for selecting a bit line to be verified/read. Then, a drain selection switch coupled to the bit line to be verified or read is driven by using the global even drain selection signal GDSLE and the global odd drain selection signal GDSLO. The bit line selector 150 could precharge both the selected bit line and unselected bit lines, thereby substantially preventing parasitic capacitance occurring between adjacent bit lines.

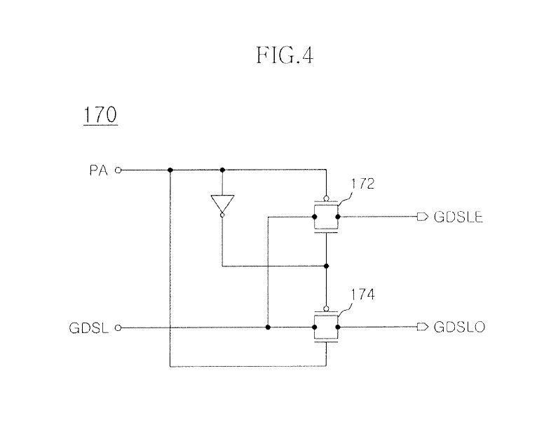

FIG. 4 is a configuration diagram of the page decoder 170 of FIG. 3.

Referring to FIG. 4, the page decoder 170 includes a first transmission gate 172 and a second transmission gate 174. The first transmission gate 172 is configured receive the global drain selection signal GDSL and output the global even drain selection signal GDSLE driven according to the page address PA and an inverted signal thereof. Similarly, the second transmission gate 174 is configured to receive the global drain selection signal GDSL and output the global odd drain selection signal GDSLO driven according to the page address PA and the inverted signal thereof.

For example, during a verification or read operation for a memory cell coupled to the even bit line BLe, the page address PA may be enabled to a low level. In this case, the global even drain selection signal GDSLE is outputted through the first transmission gate 172. Furthermore, the first switching element S11 is driven according to the block selection signal of the row decoder 120, and thus the even drain selection signal DSLE is enabled to turn on the even drain selection switch.

Meanwhile, during a verification or read operation for a memory cell coupled to the odd bit line BLo, the global odd drain selection signal GDSLO is outputted through the second transmission gate 174, and the odd drain selection signal DSLO is enabled by the second switching element S12 to turn on the odd drain selection switch.

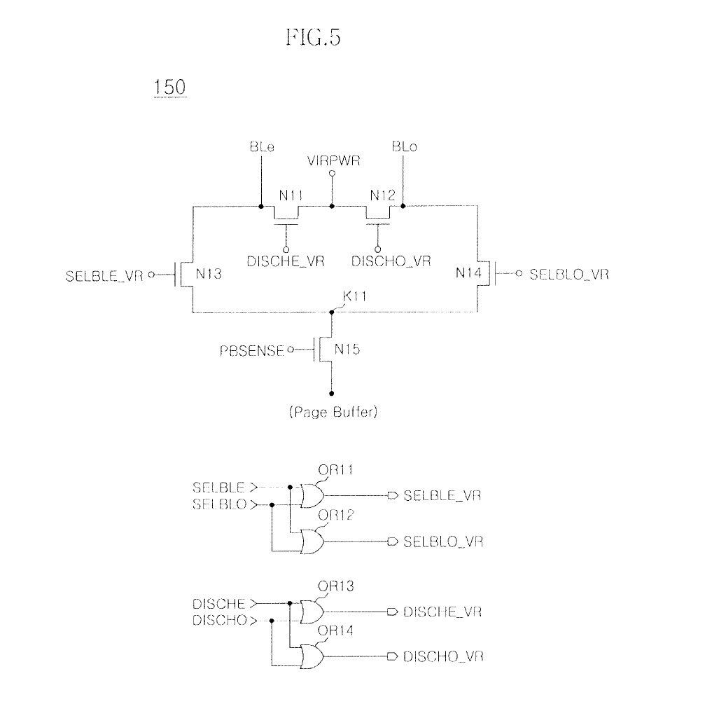

FIG. 5 is a configuration diagram of the bit line selector 150 of FIG. 3.

The bit line selector 150 as illustrated in FIG. 5 is configured to precharge adjacent bit lines with a predetermined potential during a read or verification operation regardless of which bit line is selected.

Referring to FIG. 5, the bit line selector 150 includes first to fifth switching elements N11 to N15. The first switching element N11 is coupled between the even bit line BLe and the verification voltage application terminal VIRPWR and driven by an even discharge signal DISCHE_VR. The second switching element N12 is coupled between the verification voltage application terminal VIRPWR and the odd bit line BLo and driven by an odd discharge signal DISCHO_VR. The third switching element N13 is coupled between the even bit line BLe and a first node K11 and driven by an even bit line selection signal SELBLE_VR. The fourth switching element N14 is coupled between the odd bit line BLo and the first node K11 and driven by an odd bit line selection signal SELBLO_VR. The fifth switching element N15 is coupled between the first node K11 and the page buffer 160 and driven by a sensing control signal PBSENSE.

For example, during a verification or read operation of a memory cell coupled to the even bit line BLe, a ground voltage VSS is applied to the verification voltage application terminal VIRPWR. While both the even discharge signal DISCHE_VR and the odd discharge signal DISCHO_VR are disabled, the even bit line selection signal SELBLE_VR, the odd bit line selection signal SELBLO_VR, and the sensing control signal PBSENSE are enabled. Therefore, the unselected odd bit line BLo as well as the even bit line BLe coupled to the memory cell, which is to be verified or read, are precharged with a predetermined potential.

Similarly, during a verification or read operation of a memory cell coupled to the odd bit line BLo, a ground voltage VSS is applied to the verification voltage application terminal VIRPWR. While the odd discharge signal DISCHO_VR and the even discharge signal DISCHE_VR are disabled, the odd bit line selection signal SELBLO, the even bit line selection signal SELBLE, and the sensing control signal PBSENSE are enabled. Therefore, the even bit line BLe as well as the odd bit line BLo are precharged with a predetermined potential.

That is, regardless of which bit line is selected, the even/odd discharge signals DISCHE_VR and DISCHO_VR, the even/odd bit line selection signals SELBLE_VR and SELBLO_VR, and the sensing control signal PBSENSE are enabled to precharge the adjacent bit lines, thereby substantially preventing the occurrence of parasitic capacitance caused by the potential difference.

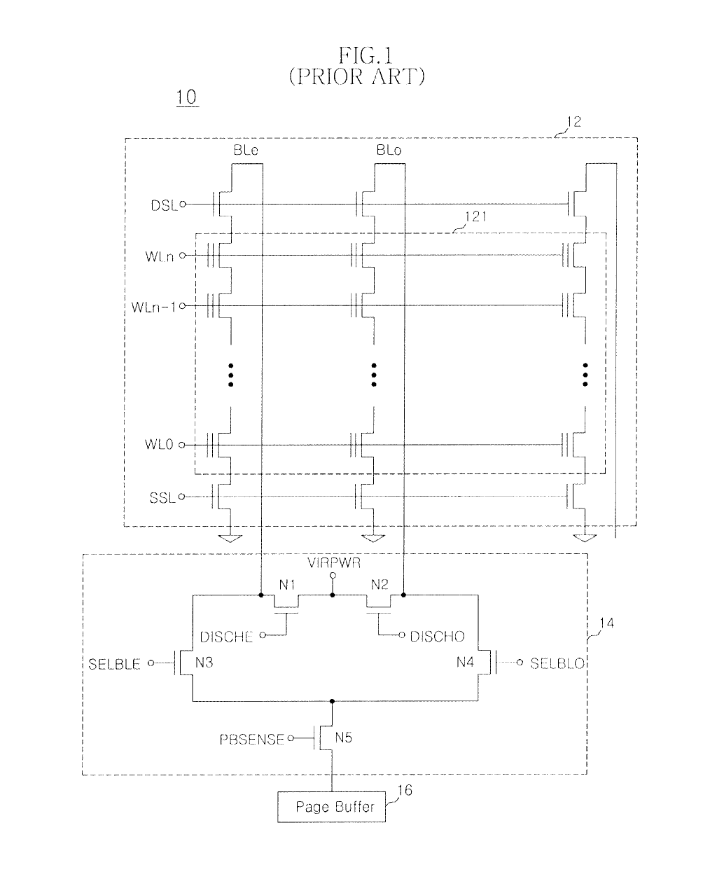

For this operation, the even/odd discharge signals DISCHE_VR and DISCHO_VR and the even/odd bit line selection signals SELBLE_VR and SELBLO_VR may be generated, for example, from the even/odd discharge signals DISCHE and DISCHO and the even/odd bit line selection signals SELBLE and SELBLO, which are shown in FIG. 1. To the contrary, in the case of the conventional bit line selector, a discharge signal and a bit line selection signal for precharging a selected bit line during a verification or read operation and a discharge signal and a bit line selection signal for applying a ground voltage to an unselected bit line are complementarily applied.

In an embodiment of the present invention, however, the selected bit line and the unselected bit line are all precharged.

Therefore, the even/odd bit line selection signals SELBLE_VR and SELBLO_VR are generated by performing an OR operation on the existing even/odd bit line selection signals SELBLE and SELBLO, and the even/odd discharge signals DISCHE_VR and DISCHO_VR are generated by performing an OR operation on the existing even/odd discharge signals DISCHE and DISCHO. For this operation, the bit line selector includes: first and second OR gates OR11 and OR12, which are configured to perform an OR operation on the even/odd bit line selection signals SELBLE and SELBLO and output the even/odd bit line selection signals SELBLE_VR and SELBLO_VR, respectively; and third and fourth OR gates OR13 and 14, which are configured to perform an OR operation on the even/odd discharge signals DISCHE and DISCHO and output the even/odd discharge signals DISCHE_VR and DISCHO_VR.

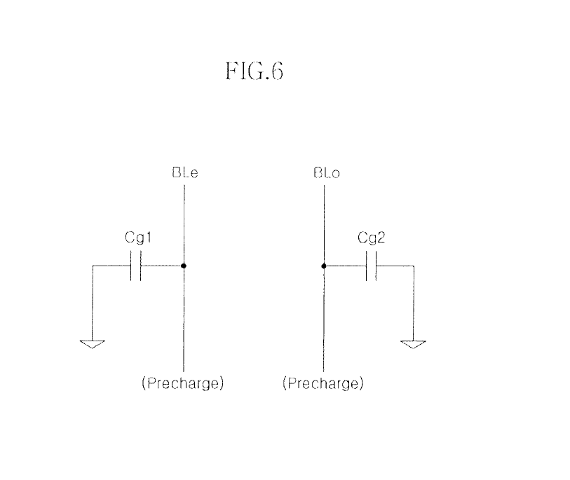

FIG. 6 is a diagram explaining an influence of parasitic capacitance in the nonvolatile memory apparatus of FIG. 3.

Since all bit lines are precharged with a predetermined potential when the even bit line BLe or the odd bit line BLo is selected, it is possible to suppress the occurrence of parasitic capacitance between the adjacent bit lines. There may exist a parasitic capacitance Cg1 occurring between the even bit line BLe and the ground terminal VSS and a parasitic capacitance Cg2 occurring between the odd bit line BLo and the ground terminal VSS. Such capacitances Cg1 and Cg2 may correspond to 10% of the capacitance occurring in the bit lines. Therefore, it is possible to significantly reduce the current consumption of the bit lines.

In a flash memory apparatus, about 50% of the entire current consumption is due to the current consumption of the bit lines. By suppressing the parasitic capacitance from occurring between the adjacent bit lines according to an embodiment of the present invention, it is possible to significantly reduce the overall current consumption of the flash memory apparatus.

Furthermore, when a specific bit line is selected to perform a verification or read operation and an unselected bit line is then selected to perform a verification or read operation, it is possible to reduce the time required for precharge.

While certain embodiments have been described above, it will be understood to those skilled in the art that the embodiments described are by way of example only. Accordingly, the nonvolatile memory apparatus described herein should not be limited based on the described embodiments. Rather, the nonvolatile memory apparatus described herein should only be limited in light of the claims that follow when taken in conjunction with the above description and accompanying drawings.

What is claimed is:

1. A nonvolatile memory apparatus comprising:
a plurality of drain selection switches respectively coupled to a plurality of memory cell strings; and
a drain selection switch controller configured to selectively drive drain selection switches, each of which is coupled to an even bit line or an odd bit line, in response to a page address and a global drain selection signal.

2. The nonvolatile memory apparatus according to claim 1, wherein the drain selection switch controller comprises:
a page decoder configured to output a global even drain selection signal and a global odd drain selection signal in response to the page address and the global drain selection signal; and
a drain selection switch driving unit configured to receive the global even drain selection signal and output an even drain selection signal for driving a drain selection switch coupled to the even bit line, and configured to receive the global odd drain selection signal and output an odd drain selection signal for driving a drain selection switch coupled to the odd bit line in response to.

3. The nonvolatile memory apparatus according to claim 1, further comprising:
a plurality of bit lines coupled to the drain selection switches, respectively; and
a bit line selector configured to precharge a selected bit line and an unselected bit line with a predetermined potential, during a verification or read operation for the memory cell strings.

4. A nonvolatile memory apparatus comprising:
a plurality of drain selection switches respectively coupled between a cell string and bit lines, the cell string including a plurality of memory cells coupled in series;
a page decoder configured to output a global even drain selection signal and a global odd drain selection signal in response to a verification or read command for the cell string; and
a drain selection switch driving unit configured to provide an even bit line or odd bit line in response to the global even drain selection signal and the global odd drain selection signal.

5. The nonvolatile memory apparatus according to claim 4, wherein the drain selection switch driving unit comprises:
a first switching element configured to receive the global even drain selection signal and output an even drain selection signal for driving a drain selection switch coupled to the even bit line, and
a second switching element configured to receive the global odd drain selection signal and output an odd drain selection signal for driving a drain selection switch coupled to the odd bit line.

6. The nonvolatile memory apparatus according to claim 4, further comprising a bit line selector configured to precharge the selected bit line and the unselected bit line with a predetermined potential, during a verification or read operation for the cell string.
